(19) United States
(12) Patent Application Publication
(10) Pub. No.: US 2025/0048525 A1
(43) Pub. Date: Feb. 6, 2025

(54) LIGHT EMITTING ELEMENT DRIVING DEVICE AND LIGHT EMITTING DEVICE

(71) Applicant: ROHM CO., LTD., Kyoto (JP)

(72) Inventor: Akira AOKI, Kyoto (JP)

(21) Appl. No.: 18/925,131

(22) Filed: Oct. 24, 2024

Related U.S. Application Data
(63) Continuation of application No. PCT/JP2023/014716, filed on Apr. 11, 2023.

(30) Foreign Application Priority Data
Apr. 27, 2022 (JP) 2022-073052

(51) Int. Cl. H05B 47/25; H05B 45/14; H05B 45/325; H05B 45/375; H05B 45/54; H05B 47/14

(52) U.S. Cl. CPC H05B 47/25; H05B 45/14; H05B 45/325; H05B 45/375; H05B 45/54; H05B 47/14

(57) ABSTRACT

A light emitting element driving device is configured to drive a light emitting element, the light emitting element driving device includes: a switch driving unit configured to drive a switch connectable to a negative end of the light emitting element the positive end of which is grounded; and an overcurrent detection unit configured to detect an overcurrent based on a voltage generated across both ends of a current detection resistor connected to a negative side of the switch and the switch driving unit is configured to switch the switch to an off-state when the overcurrent detection unit detects the overcurrent.

### CROSS-REFERENCE TO RELATED APPLICATIONS

This nonprovisional application is a continuation application of International Patent Application No. PCT/JP2023/014716 filed on Apr. 11, 2023, which claims priority Japanese Patent Application No. 2022-073052 filed on Apr. 27, 2022, the entire contents of which are hereby incorporated by reference.

### TECHNICAL FIELD

The present disclosure relates to light emitting element driving devices.

### BACKGROUND ART

An LED (light emitting diode) is an example of a light emitting element. Conventionally, an LED driving device which includes an overcurrent protection function is proposed (for example, Patent Document 1).

### RELATED ART DOCUMENT

### Patent Document

Patent Document 1: Japanese Unexamined Patent Application Publication No. 2005-206074

### BRIEF DESCRIPTION OF DRAWINGS

FIG. 1 is a diagram showing the configuration of a light emitting device which includes an LED driving device according to an illustrative first embodiment of the present disclosure;

FIG. 2 is a diagram showing examples of waveforms of an inductor current, an average LED current and a switching voltage;

FIG. 3 is a diagram showing a part of a light emitting device which uses an LED driving device according to a first comparative example;

FIG. 4 is a diagram showing a part of a light emitting device which uses an LED driving device according to a second comparative example;

FIG. 5 is a diagram showing a current path when a power short circuit occurs in the cathode of an LED in the configuration shown in FIG. 1;

FIG. 6 is a timing chart showing an example of a protection operation in the configuration of the first embodiment;

FIG. 7 is a diagram showing the configuration of a light emitting device which includes an LED driving device according to a second embodiment of the present disclosure;

FIG. 8 is a timing chart showing an example of a protection operation in the configuration of the second embodiment;

FIG. 9 is a diagram showing the configuration of a light emitting device which includes an LED driving device according to a third embodiment of the present disclosure; and

FIG. 10 is a diagram showing the configuration of a light emitting device which includes an LED driving device according to a fourth embodiment of the present disclosure.

### DESCRIPTION OF EMBODIMENTS

Illustrative embodiments of the present disclosure will be described below with reference to drawings.

### 1. First Embodiment

### <Negative Step-Up/Step-Down DC/DC Converter>

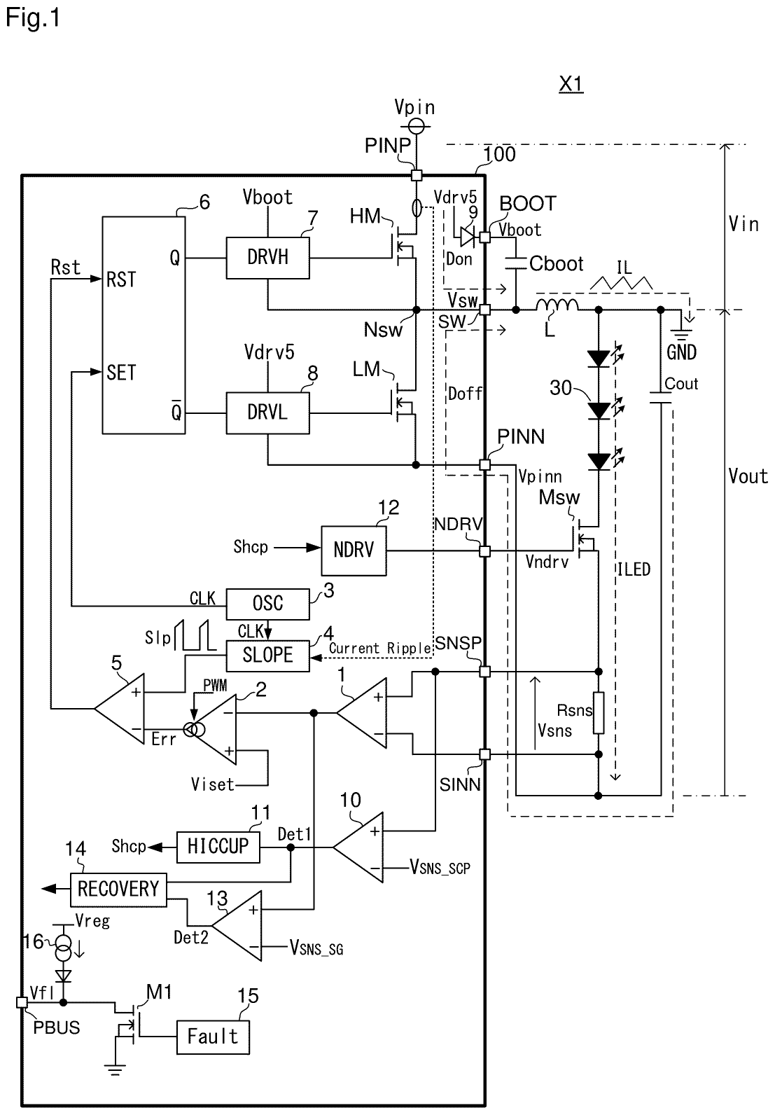

FIG. 1 is a diagram showing the configuration of a light emitting device X1 which includes an LED driving device 100 according to a first embodiment of the present disclosure. The LED driving device is an example of a light emitting element driving device. The LED driving device 100 is a semiconductor device (IC package) which drives an LED 30, and includes a negative step-up/step-down DC/DC converter function. The LED driving device 100 is, for example, a device for exterior lamps (such as a head lamp, a rear lamp and a turn lamp) in two-wheel/four-wheel vehicles.

The reason why a negative step-up/step-down function is adopted in the LED driving device 100 is that the step-up/step-down configuration is used to handle both a case where an input power supply voltage Vpin is lowered due to a decrease in the voltage of a battery or the like, and thus Vpin<forward voltage Vf of the LED 30 is satisfied, and a case where Vpin>the Vf of the LED 30 is satisfied due to the number of elements in the LED 30. Furthermore, the negative step-up/step-down function is adopted such that when the anode of the LED 30 is short-circuited to the application end of the Vpin, a protection circuit is not needed.

As shown in FIG. 1, the LED driving device 100 includes an amplifier 1, an error amplifier 2, an oscillator 3, a slope generation unit 4, a PWM comparator 5, a flip-flop 6, an upper driver 7, a lower driver 8, a diode 9, a comparator 10, a HICCUP control unit 11, a switch driving unit 12, a comparator 13, a recovery state monitoring unit 14, an abnormality control unit 15, a constant current circuit 16, a transistor M1, an upper transistor HM and a lower transistor LM by integrating them into one chip.

The LED driving device 100 includes, as external terminals for establishing electrical connection with the outside, a PINP terminal (input power supply terminal), a BOOT terminal (bootstrap capacitance connection terminal), an SW terminal (switching output terminal), a PINN terminal (DC/DC negative reference input terminal), an SNSP terminal (LED current detection+connection terminal), an SINN terminal (small signal negative reference input terminal), an NDRV terminal (switch driving terminal) and a PBUS terminal (flag output terminal).

Outside the LED driving device 100, an inductor L, an output capacitor Cout, the LED 30, a switch Msw, a sense resistor Rsns and a boot capacitor Cboot are arranged. The light emitting device X1 includes the LED driving device 10 and the external elements as described above.

A DC/DC converter includes the upper transistor HM, the lower transistor LM, the inductor L and the output capacitor Cout, and is subjected to switching control performed by the LED driving device 10 to generate an output voltage Vout based on an input voltage Vin. The output voltage Vout is applied to the LED 30 serving as a load.

One end of the inductor L is connected to the SW terminal. The other end of the inductor L is connected to the anode of the LED 30 and one end of the output capacitor Cout, and is grounded by being connected to the application end of a ground GND. The ground GND is the reference potential of an application.

The switch Msw is formed with an N-channel MOSFET (metal-oxide-semiconductor field-effect transistor). The switch Msw is also called a load switch. The drain of the switch Msw is connected to the cathode of the LED 30. The source of the switch Msw is connected to one end of the sense resistor Rsns. The other end of the sense resistor Rsns and the other end of the output capacitor Cout are connected to the PINN terminal.

The application end of the input power supply voltage Vpin is connected to the PINP terminal. The input power supply voltage Vpin is the voltage of the battery, and is, for example, 12V with reference to the ground GND.

The upper transistor HM and the lower transistor LM each are formed with an N-channel MOSFET, and are connected in series between the PINP terminal and the PINN terminal to form a bridge. More specifically, the drain of the upper transistor HM is connected to the PINP terminal. The source of the upper transistor HM and the drain of the lower transistor LM are connected to a node Nsw. The source of the lower transistor LM is connected to the PINN terminal. The node Nsw is connected to the SW terminal.

One end of the sense resistor Rsns is connected to the SNSP terminal. The other end of the sense resistor Rsns is connected to the SINN terminal.

One input terminal of the amplifier 1 is connected to the SNSP terminal. The other input terminal of the amplifier 1 is connected to the SINN terminal. A current flowing through the LED 30 is transformed by the sense resistor Rsns into a sense voltage Vsns generated across both ends of the sense resistor Rsns. The amplifier 1 amplifies the sense voltage Vsns which is input with a predetermined gain. For example, the amplifier 1 amplifies the sense voltage Vsns by a factor of 12.5.

The output of the amplifier 1 is input to one input end of the error amplifier 2. A setting voltage Viset is applied to the other input end of the error amplifier 2. The error amplifier 2 amplifies an error of signals input to the two input terminals to generate an error signal Err.

Here, the LED driving device 10 includes a PWM dimming function. PWM dimming refers to a method for performing dimming by switching the turning on and off of an LED at several hundred Hz to several kHz, and the brightness of the LED is determined by a duty factor in one period of a PWM dimming signal (“PWM” in FIG. 1). When the PWM dimming signal is high, the error amplifier 2 performs a normal operation whereas when the PWM dimming signal is low, the error amplifier 2 stops the normal operation to perform an output maintenance operation. In this way, when the PWM dimming signal reaches a high level, the operation of the error amplifier 2 can be started with the output of the error amplifier 2 immediately before the signal falls to the immediately preceding low level. Hence, it is possible to reduce the amount of variation in an LED current as much as possible.

The oscillator 3 generates a clock signal CLK having a fixed frequency (for example, 400 kHz). The slope generation unit 4 generates a slope signal Slp having the fixed frequency based on the clock signal CLK. The slope signal Slp is generated based on the current ripple information of a current flowing through the upper transistor HM.

The slope signal Slp is input to the non-inverting input terminal (+) of the PWM comparator 5. The error signal Err is input to the inverting input terminal (−) of the PWM comparator 5. The output Rst of the PWM comparator 5 is input to the reset terminal of the flip-flop 6. The clock signal CLK is input to the set terminal of the flip-flop 6.

The upper driver 7 drives the gate of the upper transistor HM based on the Q terminal output of the flip-flop 6 to subject the upper transistor HM to switching driving. The upper driver 7 applies a voltage between a boot voltage Vboot and the switching voltage Vsw of the SW terminal to the gate of the upper transistor HM.

The boot capacitor Cboot for bootstrap is connected between the BOOT terminal and the SW terminal. The application end of an internal reference voltage Vdrv5 is connected to the anode of the diode 9. The BOOT terminal is connected to the cathode of the diode 9. By charging the boot capacitor Cboot, the boot voltage Vboot is generated at the BOOT terminal. With the boot voltage Vboot, it is possible to bring the upper transistor HM into an on-state.

The lower driver 8 drives the gate of the lower transistor LM based on the Q bar terminal output of the flip-flop 6 to subject the lower transistor LM to switching driving. The lower driver 8 applies a voltage between the internal reference voltage Vdrv5 and the voltage of the PINN terminal to the gate of the lower transistor LM.

In the configuration as described above, the LED driving device 10 performs feedback control with an LED average current ILED flowing through the LED 30, and thereby can supply a current stable for the input power supply voltage Vpin and an LED load variation to the LED 30. During normal operation, the switch Msw is controlled to be in an on-state.

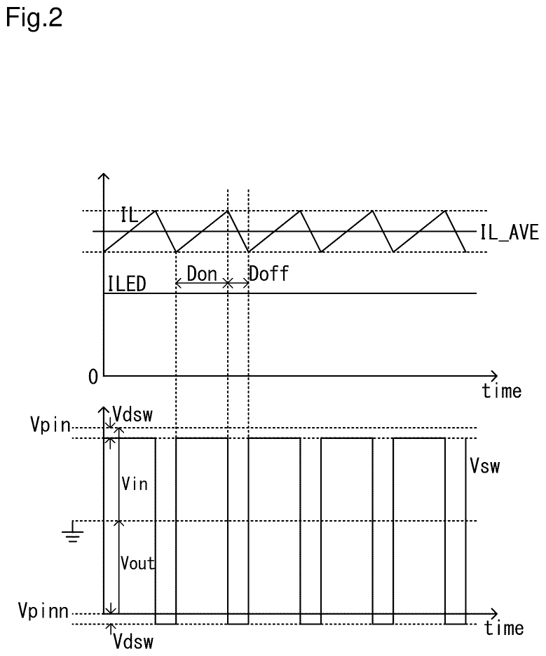

Here, FIG. 2 shows examples of waveforms of an inductor current IL flowing through the inductor L, an inductor average current IL_AVE, the LED average current ILED and the switching voltage Vsw. A voltage drop Vdsw shown in FIG. 2 is a voltage drop caused by the on-resistance of the upper transistor HM or the on-resistance of the lower transistor LM. The flip-flop 6 is set by the clock signal CLK, the upper transistor HM is turned on, the lower transistor LM is turned off and thus an on-period Don (FIG. 2) is started. During the on-period Don, a current flows (along a current path indicated by “Don” in FIG. 1) via the upper transistor HM in an on-state and the SW terminal, and thus the inductor current IL is increased. Here, excitation energy is stored in the inductor L.

Then, the flip-flop 6 is reset by the output of the PWM comparator 5, the upper transistor HM is turned off, the lower transistor LM is turned on and thus an off-period Doff (FIG. 2) is stated. During the off-period Doff, a current flows (along a current path indicated by “Doff” in FIG. 1) by the excitation energy stored in the inductor L via the lower transistor LM in an on-state and the SW terminal, and thus the inductor current IL is reduced. Here, since the other end of the inductor L is grounded by being connected to the application end of the ground GND, the output capacitor Cout is charged negatively. In this way, a negative reference voltage Vpinn is generated at the PINN terminal and the SINN terminal.

Then, when the flip-flop 6 is set again by the fixed frequency of the clock signal CLK, the upper transistor HM is turned on, and thus the on-period Don is started again.

Inductor peak current control is performed by turning off the upper transistor HM, and thus the inductor average current IL_AVE is controlled such that the LED average current ILED is set to a target setting current.

As shown in FIG. 1, the input voltage Vin between the ground GND and the input power supply voltage Vpin is stepped up or down to the output voltage Vout between the negative reference voltage and the ground GND.

### <Overcurrent Protection>

In the configuration shown in FIG. 1, the cathode of the LED 30 may be short-circuited to the input power supply voltage Vpin. In other words, the cathode of the LED 30 may be short-circuited to power. When the power short circuit as described above occurs, since an overcurrent is generated, it is necessary to provide a protection function.

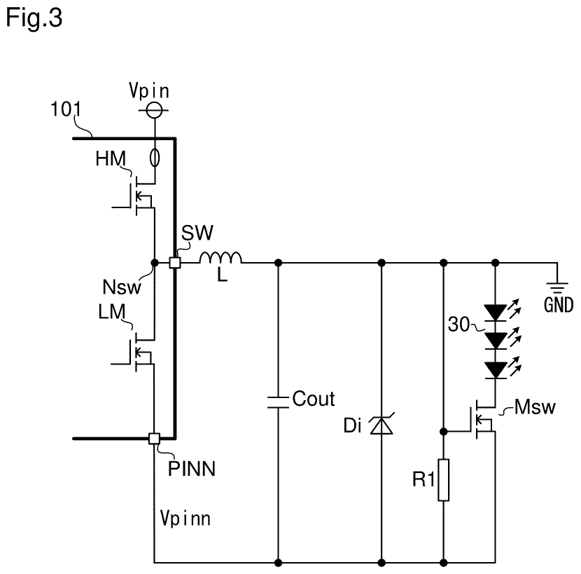

Here, FIG. 3 is a diagram showing a part of a light emitting device which uses an LED driving device 101 according to a first comparative example. The LED driving device 101 shown in FIG. 3 differs from the configuration shown in FIG. 1 in that feedforward control can be performed. The LED driving device 101 includes an upper transistor HM and a lower transistor LM. The LED driving device 101 includes a SW terminal and a PINN terminal as external terminals. Outside the LED driving device 101, an inductor L, an output capacitor Cout, a clamp diode Di, a resistor R1, a switch Msw and an LED 30 are provided.

A node Nsw to which the upper transistor HM and the lower transistor LM are connected is connected to one end of the inductor L via the SW terminal. The other end of the inductor L is connected to one end of the output capacitor Cout and is grounded. The anode of the LED 30 is connected to the other end of the inductor L. The cathode of the LED 30 is connected to the PINN terminal via the switch Msw. The gate of the switch Msw is connected to the other end of the inductor L. The resistor R1 is connected between the gate of the switch Msw and the PINN terminal. The cathode of the clamp diode Di is connected to the other end of the inductor L. The anode of the clamp diode Di is connected to the PINN terminal.

In the configuration as described above, the upper transistor HM and the lower transistor LM are switched, and thus the PINN terminal is controlled to have a negative voltage. By a potential difference between a ground potential and a voltage at the PINN terminal, the switch Msw is brought into an on-state. The clamp diode Di clamps a voltage Vpinn at the PINN terminal such that Vpinn≤GND+VF (VF: forward voltage of clamp diode Di).

However, in the configuration shown in FIG. 3, when a power short circuit occurs in the cathode of the LED 30, though an overcurrent flows toward the GND through the switch Msw and the clamp diode Di, the overcurrent cannot be detected. Hence, it is impossible to perform protection (power short circuit protection) against the overcurrent.

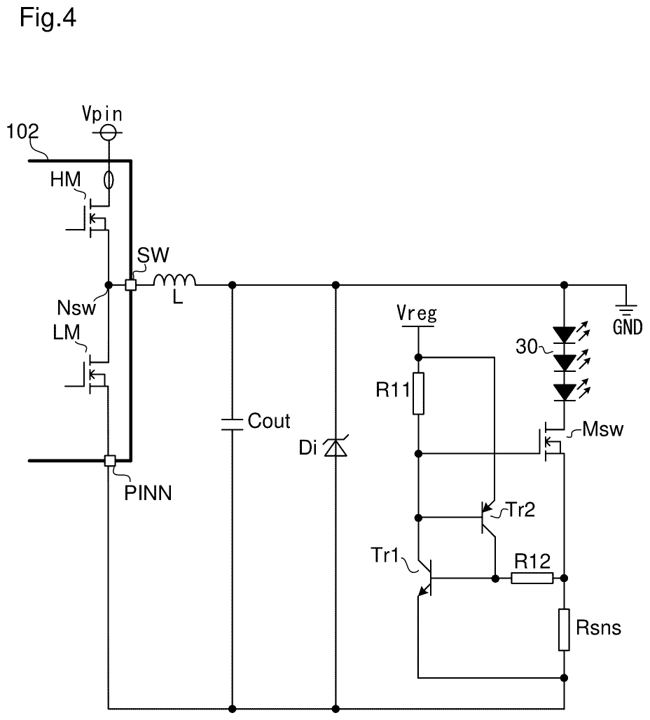

FIG. 4 is a diagram showing a part of a light emitting device which uses an LED driving device 102 according to a second comparative example. The LED driving device 102 shown in FIG. 4 is configured to be able to perform feedback control as in the configuration shown in FIG. 1. In the configuration shown in FIG. 4, a sense resistor Rsns is provided between the switch Msw and a PINN terminal. A current flowing through an LED 30 is detected with the sense resistor Rsns, and thus the feedback control is performed.

The configuration shown in FIG. 4 differs from the configuration shown in FIG. 3 in that outside the LED driving device 102, resistors R11 and R12 and bipolar transistors Tr1 and Tr2 are provided. One end of the resistor R11 is connected to the application end of an internal voltage Vreg. The internal voltage Vreg is generated inside the LED driving device 102. The other end of the resistor R11 is connected to the gate of the switch Msw.

The bipolar transistor Tr1 is formed with an NPN transistor. The collector of the bipolar transistor Tr1 is connected to the other end of the resistor R11. The emitter of the bipolar transistor Tr1 is connected to the PINN terminal. The base of the bipolar transistor Tr1 is connected to one end of the resistor R12. The other end of the resistor R12 is connected to one end of the sense resistor Rsns. The bipolar transistor Tr2 is formed with a PNP transistor. The emitter of the bipolar transistor Tr2 is connected to the application end of the internal voltage Vreg. The collector of the bipolar transistor Tr2 is connected to the base of the bipolar transistor Tr1. The base of the bipolar transistor Tr2 is connected to the collector of the bipolar transistor Tr1.

In the configuration as described above, when a power short circuit occurs in the cathode of the LED 30, an overcurrent flows through the sense resistor Rsns. Here, a voltage generated by the overcurrent Iocp across both ends of the sense resistor Rsns exceeds the vfpnp of the bipolar transistor Tr1. In other words, Iocp>Vfpnp/Rsns is satisfied. In this way, the bipolar transistor Tr1 is turned on, the gate of the switch Msw has a voltage at the PINN terminal and the switch Msw is turned off. Here, since the bipolar transistor Tr2 is turned on, the state of the bipolar transistors Tr1 and Tr2 is latched. Hence, the switch Msw in an on-state is latched. If only the bipolar transistor Tr1 is provided, and the switch Msw is not latched, a current which is restricted by the bipolar transistor Tr1 to have a value of Vfpnp/Rsns continues to flow, with the result that heat is generated.

However, in the configuration shown in FIG. 4, even when noise occurs to increase a voltage across both ends of the sense resistor Rsns, and thus the voltage exceeds the Vfpnp of the bipolar transistor Tr1, the bipolar transistors Tr1 and Tr2 and the switch Msw are disadvantageously latched. When they are latched, automatic recovery cannot be disadvantageously achieved. The resistors R11 and R12 and the bipolar transistors Tr1 and Tr2 are needed, and thus the number of elements outside the LED driving device 102 is disadvantageously increased.

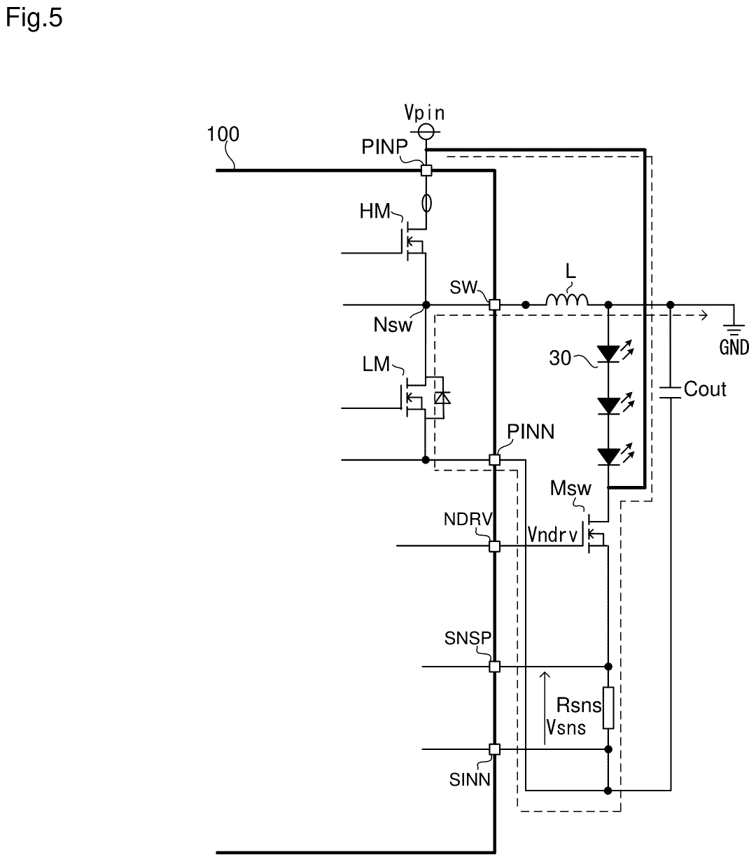

FIG. 5 is a diagram showing a current path when a power short circuit occurs in the cathode of the LED 30 in the configuration shown in FIG. 1. In FIG. 5, the cathode of the LED 30 is short-circuited to the application end of the input power supply voltage Vpin, and thus a current path (dashed lines in FIG. 5) is generated which extends from the application end of the input power supply voltage Vpin to the application end of the ground potential via the switch Msw, the sense resistor Rsns, the PINN terminal, the body diode of the lower transistor LM, the SW terminal and the inductor L, with the result that an overcurrent flows through the current path. However, the LED driving device 100 of the configuration shown in FIG. 1 according to the present disclosure includes a protection function against the overcurrent as described above.

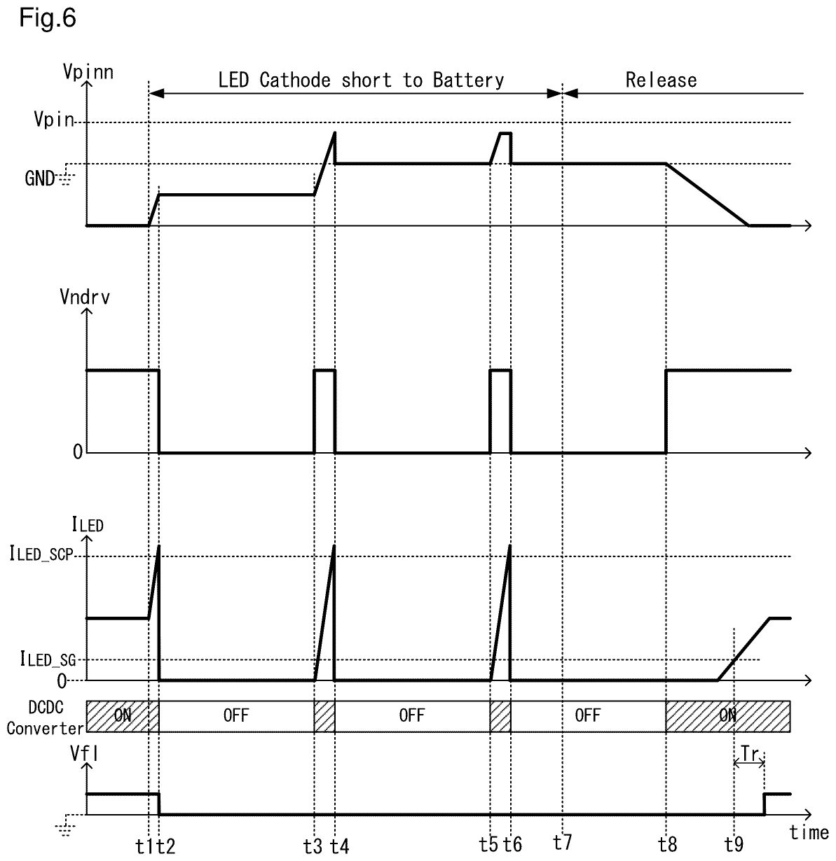

Such a protection function will be described with reference to a timing chart shown in FIG. 6. FIG. 6 shows, sequentially from the top row, examples of waveforms of the voltage Vpinn at the PINN terminal, a drive voltage Vndrv applied by the switch driving unit 12 to the gate of the switch Msw, an LED current I_{LED} flowing through the sense resistor Rsns, the on/off state of the DC/DC converter in the configuration shown in FIG. 1 and an abnormal flag Vf1.

A path is included in which the LED current ILED does not pass through the LED 30 as shown in FIG. 5 when a power short circuit occurs in the cathode of the LED 30.

As shown in FIG. 1, the PBUS terminal is a terminal for outputting the abnormal flag Vf1. The transistor M1 is formed with an N-channel MOSFET. The drain of the transistor M1 is connected to the PBUS terminal. The constant current circuit 16 is connected between the PBUS terminal and the application end of the internal voltage Vreg. The source of the transistor M1 is grounded. The transistor M1 is driven by the abnormality control unit 15. In a normal state, the abnormality control unit 15 controls the transistor M1 such that the transistor M1 is in an off-state, and thus the abnormal flag Vf1 is kept high. When an abnormality occurs, the abnormality control unit 15 controls the transistor M1 such that the transistor M1 is brought into an on-state, and thus the abnormal flag Vf1 is turned low.

In FIG. 6, during normal operation, the DC/DC converter is first in an on-state, the drive voltage Vndrv is kept high by the switch driving unit 12 and thus the switch Msw is in an on-state. Here, the voltage Vpinn at the PINN terminal is negative, and thus the LED current ILED is controlled to be a predetermined current value. The abnormal flag Vf1 is high.

Then, when a power short circuit occurs in the cathode of the LED 30 at a timing t1, an overcurrent is generated, and thus the LED current I_{LED} is rapidly increased. Here, the voltage Vpinn at the PINN terminal is increased toward a positive voltage close to the input power supply voltage Vpin.

Here, an overcurrent setting value I_{LED_SCP} is represented as follows.

$${I}_{LED \_ SCP} = {V}_{SNS \_ SCP} / Rsns$$

where V_{SNS_SCP} is an overcurrent setting value for the sense voltage Vsns which is a voltage across both ends of the sense resistor Rsns.

The comparator 10 (FIG. 1) compares the sense voltage Vsns with the overcurrent setting value V_{SNS_SCP}. In this way, the fact that the LED current I_{LED} is rapidly increased at the timing t1 to exceed the overcurrent setting value I_{LED_SCP} is detected by the fact that sense voltage Vsns exceeds the overcurrent setting value V_{SNS_SCP}. Here, the comparator 10 outputs a high-level detection output Det1.

The HICCUP control unit 11 outputs a control output Shcp according to the detection output Det1. When the high-level detection output Det1 is input, the HICCUP control unit 11 outputs, for example, a high-level control output Shcp. The switch driving unit 12 drives the switch Msw according to the control output Shcp. When the high-level control output Shop is input, the switch driving unit 12 determines that an overcurrent is detected, and thereby switches the drive voltage Vndrv from high to low to switch the switch Msw from an on-state to an off-state (at a timing t2). Here, the DC/DC converter is switched from an on-state to an off-state. In this way, the LED current ILED does not flow (I_{LED}=0). Hence, the state transitions to a protected state.

When the high-level detection output Det1 is input, the HICCUP control unit 11 starts to count a predetermined standby time. During the standby time, the switch Msw and the DC/DC converter are kept in the off state. Then, when the standby time has elapsed, the HICCUP control unit 11 outputs a low-level control output Shcp. When the switch driving unit 12 receives it, the switch driving unit 12 switches the drive voltage Vndrv from low to high, and thereby switches the switch Msw from the off-state to the on-state (at a timing t3). Here, the DC/DC converter is switched from the off-state to the on-state. In this way, the state recovers from the protected state.

Here, since the power short circuit is not released, an overcurrent is generated again, and thus the LED current ILED is rapidly increased. Hence, as described above, the overcurrent is detected by the comparator 10, and the switch Msw and the DC/DC converter are switched to the off-state again (at a timing t4). Therefore, the state is switched to the protected state again. Here, the voltage Vpinn is increased toward the positive voltage described above, and when the switch Msw is brought into the off-state after the voltage Vpinn exceeds the ground potential, the voltage Vpinn falls to the ground potential.

Then, as described above, when the standby time has elapsed, the HICCUP control unit 11 switches the switch Msw and the DC/DC converter to the on-state, and thus the recovery is performed (at a timing t5). Here, since the power short circuit has not been released, an overcurrent is generated again, and thus the LED current ILED is rapidly increased. Therefore, as described above, the overcurrent is detected by the comparator 10, and the switch Msw and the DC/DC converter are switched to the off-state again (at a timing t6). Consequently, the state is switched to the protected state again. Here, the voltage Vpinn is increased toward the positive voltage described above, and when the voltage Vpinn reaches the positive voltage, the positive voltage is kept, with the result that when the switch Msw is brought into the off-state, the voltage Vpinn falls to the ground potential.

Then, in FIG. 6, the power short circuit is released before the standby time has elapsed (at a timing t7). Thereafter, when the standby time has elapsed, the HICCUP control unit 11 switches the switch Msw and the DC/DC converter to the on-state, and thus the recovery is performed (at a timing t8). Here, since the power short circuit has been released, the Vpinn is lowered toward a negative voltage, and thus the LED current ILED flows while the Vpinn is being lowered. The LED current ILED does not reach an overcurrent, and when the LED current ILED is increased to a steady state, the LED current ILED becomes constant. Hence, an overcurrent is not detected by the comparator 10, and thus the switch Msw is kept in the on-state by the switch driving unit 12.

As described above, when a power short circuit occurs in the cathode of the LED 30, the protected state and the recovery are repeated, and when the power short circuit is released, it is possible to return to the normal state by the recovery. In other words, while the protection against an overcurrent is being performed, automatic recovery can be performed when the power short circuit is released.

Even if an overcurrent is detected due to noise, since this is not caused by the occurrence of a power short circuit, an overcurrent is not detected when the recovery is subsequently performed, with the result that the automatic recovery to the normal state is performed.

As described above, the control is preformed inside the LED driving device 10 by the comparator 10, the HICCUP control unit 11 and the switch driving unit 12, and thus it is possible to realize the protection operation and the recovery. As in the second comparative example described above, it is possible to suppress an increase in the number of elements outside the LED driving device.

The abnormal flag Vf1 will be described. When an overcurrent is detected during normal operation, the transistor M1 is turned on by the abnormality control unit 15, and thus the abnormal flag Vf1 is switched to a low level which indicates an abnormality (at the timing t2). Thereafter, the recovery state monitoring unit 14 detects, based on the detection output Det2 of the comparator 13, that the LED current ILED is increased from 0 to exceed a predetermined threshold value I_{LED_SG}, the recovery state monitoring unit 14 monitors the detection output Det1 of the comparator 10. Here, the comparator 13 compares the output of the amplifier 1 with a threshold value V_{SNS_SG}. Threshold value V_{SNS_SG}=I_{LED_SG}×Rsns is satisfied.

The recovery state monitoring unit 14 monitors whether the LED current ILED exceeds the overcurrent setting value I_{LED_SCP} before a predetermined monitoring time Tr has elapsed. When the LED current ILED exceeds the overcurrent setting value I_{LED_SCP}, the recovery state monitoring unit 14 uses the abnormality control unit 15 to keep the transistor M1 in an on-state, and to keep the abnormal flag Vf1 low. Hence, in the timings t4 and t6 in FIG. 6, the LED current ILED exceeds the overcurrent setting value I_{LED_SCP} before the predetermined monitoring time Tr has elapsed, and thus the abnormal flag Vf1 is kept low.

On the other hand, when the LED current ILED does not exceed the overcurrent setting value I_{LED_SCP} before the predetermined monitoring time Tr has elapsed, the recovery state monitoring unit 14 uses the abnormality control unit 15 to switch the transistor M1 to an off-state, and to switch the abnormal flag Vf1 high. In this way, before the predetermined monitoring time Tr has elapsed since a timing t9 (at which the LED current ILED exceeds the threshold value I_{LED_SG}) after the release of the power short circuit, the LED current ILED does not exceed the overcurrent setting value I_{LED_SCP}, with the result that the abnormal flag Vf1 is switched high.

The comparator 10 which detects an overcurrent may compare the output of the amplifier 1 with the reference voltage. However, in the configuration shown in FIG. 1, the sense voltage Vsns is directly compared with the reference voltage, and thus it is possible to more suppress a delay in the detection of an overcurrent.

### 2. Second Embodiment

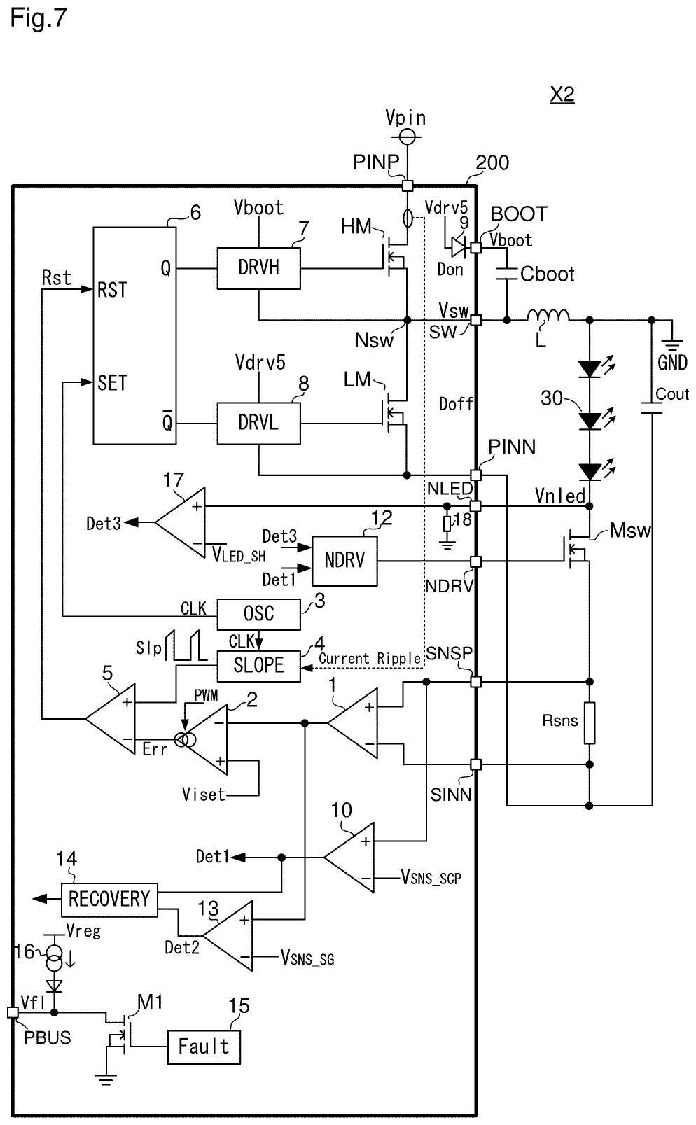

FIG. 7 is a diagram showing the configuration of a light emitting device X2 which includes an LED driving device 200 according to a second embodiment of the present disclosure. The LED driving device 200 differs from the LED driving device in the first embodiment (FIG. 1) described above in that the LED driving device 200 includes a comparator 17, a pull-down resistor 18 and an NLED terminal (cathode connection terminal).

One input end of the comparator 17 is connected to the cathode of an LED 30 via the NLED terminal. In this way, the comparator 17 compares the cathode voltage Vnled of the LED 30 with a power short circuit detection threshold value V_{LED_SH}. When the cathode voltage Vnled exceeds the power short circuit detection threshold value V_{LED_SH}, the comparator 17 detects a power short circuit to output a high-level detection output Det3. The detection output Det1 of the comparator 10 and the detection output Det3 of the comparator 17 are input to a switch driving unit 12.

The NLED terminal is pulled down to the ground potential by the pull-down resistor 18. In this way, it is possible to prevent a voltage at the NLED terminal (cathode voltage Vnled) from becoming unstable when a switch Msw is in the off state.

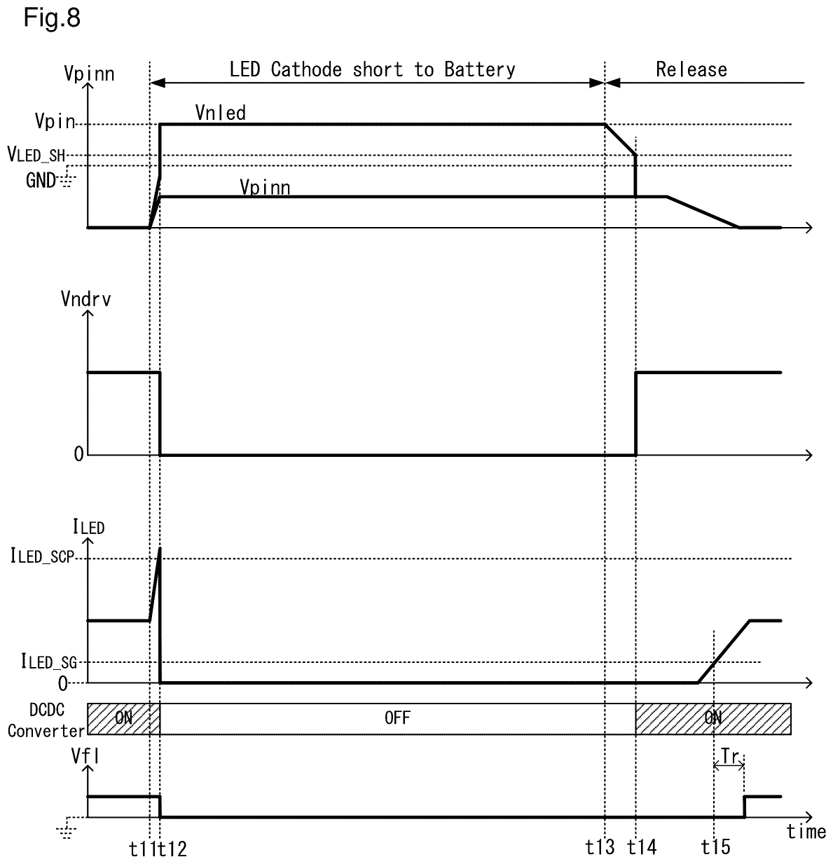

A protection function in the LED driving device 200 of the configuration described above will be described with reference to a timing chart shown in FIG. 8. FIG. 8 shows, sequentially from the top row, examples of waveforms of a voltage Vpinn, the cathode voltage Vnled, a drive voltage Vndrv, an LED current ILED, the on/off state of a DC/DC converter in the configuration shown in FIG. 7 and an abnormal flag Vf1.

When in the normal state, a power short circuit occurs at a timing t11, an overcurrent is generated, and thus the LED current I_{LED} is rapidly increased. Then, when the overcurrent is detected by the comparator 10, the switch driving unit 12 switches the switch Msw from an on-state to an off-state, and also switches the DC/DC converter from an on-state to an off-state (timing t12). In this way, the LED current I_{LED} falls to 0. Here, the voltage Vpinn at a PINN terminal and the cathode voltage Vnled are increased from a negative voltage, thus the switch Msw is turned off to keep the voltage Vpinn and the cathode voltage Vnled instantly rises to an input power supply voltage Vpin.

In this way, the cathode voltage Vnled exceeds the power short circuit detection threshold value V_{LED_SH}, and thus the detection output Det3 of the comparator 17 is switched from low to high. The power short circuit detection threshold value V_{LED_SH} is set higher than the ground potential.

When the detection threshold value Det3 is high, the switch driving unit 12 keeps the switch Msw in the off-state. In FIG. 8, the power short circuit is kept from the timing t12 to a timing t13, and thus the switch Msw is kept in the off-state. Hence, the protected state is kept. Then, when the power short circuit is released at the timing t13, the cathode voltage Vnled is lowered toward the ground potential by the pull-down resistor 18.

Then, when the comparator 17 detects that the cathode voltage Vnled has been lowered to the power short circuit detection threshold value V_{LED_SH}, the switch driving unit 12 switches the switch Msw from the off-state to the on-state (timing t14). Here, the DC/DC converter is also switched from the off-state to the on-state. Hence, the recovery is performed.

Then, the cathode voltage Vnled matches the Vpinn, and is lowered toward a negative voltage. Here, the LED current I_{LED} rises from 0, and reaches a steady state value so as to be constant.

As described above, in the present embodiment, while a power short circuit occurs, as in the first embodiment, the protected state can be kept without recovery. Then, when the power short circuit is released, automatic recovery can be performed. When an overcurrent is detected by the comparator 10 due to noise, though the state is switched to the protected state, since a power short circuit does not occur, the cathode voltage Vnled is the ground potential, and the detection output Det3 of the comparator 17 is low, with the result that the switch driving unit 12 instantly switches the switch Msw to the on-state. Hence, the recovery can be performed instantly.

### 3. Third Embodiment

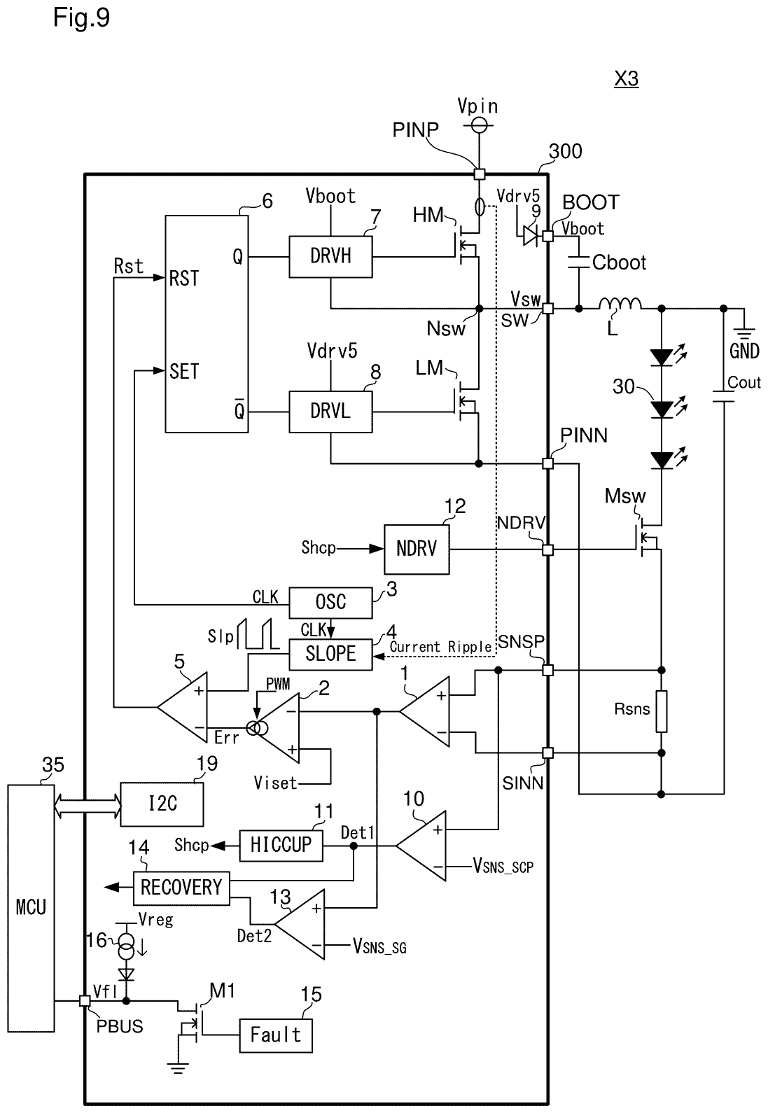

FIG. 9 is a diagram showing the configuration of a light emitting device X3 which includes an LED driving device 300 according to a third embodiment of the present disclosure. The LED driving device 300 differs from the LED driving device in the first embodiment (FIG. 1) in that the LED driving device 300 includes a communication unit 19. The communication unit 19 communicates with a microcomputer 35 which is provided outside the LED driving device 300. In the example of FIG. 9, communication using I2C is performed. An abnormality flag Vf1 is notified to the microcomputer 35.

The microcomputer 35 can set the enablement or the disablement of a function for performing recovery from the protected state to a register in the communication unit 19 by communication. In this way, when the disablement of the recovery is selected, during normal operation, an overcurrent is detected by the comparator 10, a switch Msw and a DC/DC converter are switched to an off-state and thereafter a switch driving unit 12 keeps the switch Msw in the off-state without depending on a HICCUP control unit 11.

The communication unit and the microcomputer can be applied to the second embodiment.

### 4. Fourth Embodiment

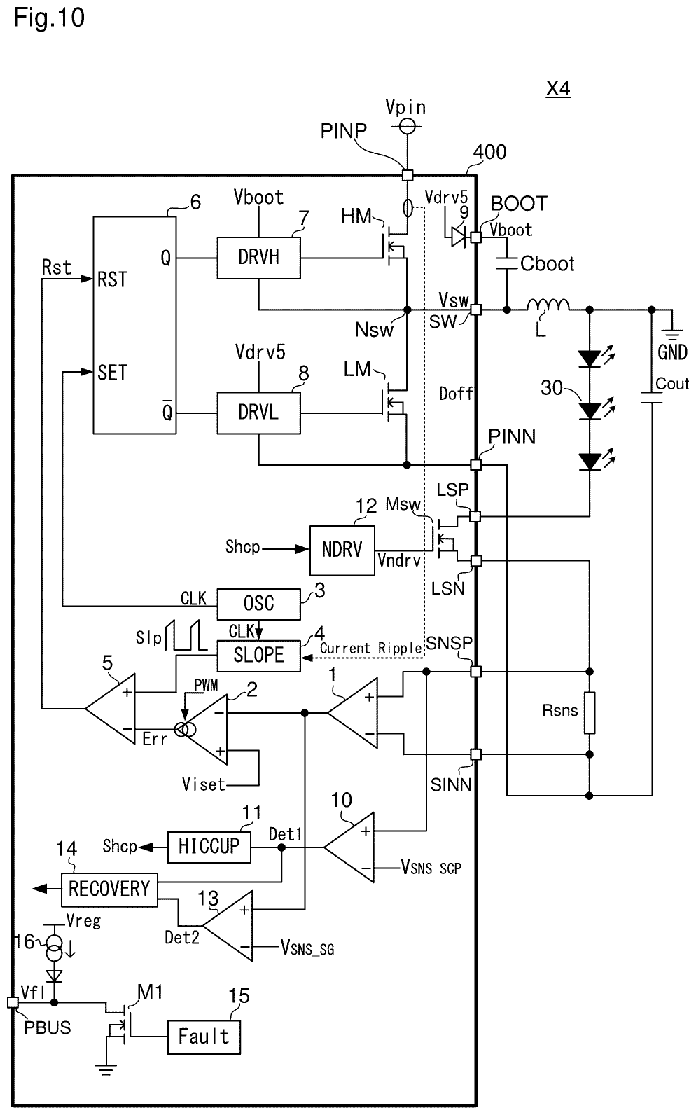

FIG. 10 is a diagram showing the configuration of a light emitting device X4 which includes an LED driving device 400 according to a fourth embodiment of the present disclosure. The LED driving device 400 differs from the LED driving device in the first embodiment (FIG. 1) in that the LED driving device 400 incorporates a switch Msw. In this way, the LED driving device 400 includes an LSP terminal to which the drain of the switch Msw is connected and an LSN terminal to which the source of the switch Msw is connected.

As described above, the switch Msw is incorporated, and thus it is possible to suppress a delay in the turning off of the switch Msw when an overcurrent is detected and thus the switch driving unit 12 switches a drive voltage Vndrv low. In the second and third embodiments, the switch Msw may be incorporated.

### 5. Others

In the various technical features disclosed in the present specification, in addition to the embodiments described above, various modifications can be made without departing from the spirit of the technical creation thereof. In other words, the embodiments described above should be considered to be illustrative in all respects and not restrictive. It should be understood that the technical scope of the present invention is not limited to the embodiments described above, and meanings equivalent to the scope of claims and all modifications in the scope are included therein.

### 6. Additional Description

As described above, a light emitting element driving device (100) according to an aspect of the present disclosure is configured to drive a light emitting element (30), the light emitting element driving device includes: a switch driving unit (12) configured to drive a switch (Msw) connectable to a negative end (cathode) of the light emitting element the positive end (anode) of which is grounded; and an overcurrent detection unit (10) configured to detect an overcurrent based on a voltage generated across both ends of a current detection resistor (Rsns) connected to a negative side of the switch and the switch driving unit is configured to switch the switch to an off-state when the overcurrent detection unit detects the overcurrent (first configuration).

In the first configuration described above, the light emitting element driving device may further include: a recovery control unit (11) configured to control the switch driving unit (12) such that when the overcurrent detection unit (10) detects the overcurrent, the switch driving unit switches the switch (Msw) to an on-state after a predetermined standby time has elapsed (second configuration).

In the first or second configuration described above, the light emitting element driving device may further include: a power short circuit detection unit (17) configured to compare a voltage at the negative end of the light emitting element (30) with a power short circuit detection threshold value, and the switch driving unit (12) may be configured to keep the switch (Msw) in the off-state while the power short circuit detection unit detects a power short circuit after the overcurrent detection unit (10) has detected the overcurrent (third configuration).

In the third configuration described above, the negative end of the light emitting element (30) may be pulled down to a ground potential, and the switch driving unit (12) may be configured to switch the switch (Msw) to the on-state when the power short circuit detection unit (17) detects that the voltage at the negative end has been lowered to the power short circuit detection threshold value (fourth configuration).

In any one of the first to fourth configurations described above, the light emitting element driving device may further include: a communication unit (19) configured to communicate with a microcomputer (35), and whether to recover from a protected state after the overcurrent has been detected according to information set by the microcomputer to the communication unit may be switched (fifth configuration).

In any one of the first to fifth configurations described above, the light emitting element driving device may further include: an amplifier (1) configured to amplify the voltage across the both ends of the current detection resistor (Rsns), and the overcurrent detection unit (10) may be a comparator connected to a front stage side of the amplifier (sixth configuration)

A light emitting device (X1) according to an aspect of the present disclosure includes: the light emitting element driving device (100) in any one of the configurations described above; a light emitting element (30) that is driven by the light emitting element driving device; a switch (Msw) that is connected to a negative end of the light emitting element; and a current detection resistor (Rsns) that is connected to a negative side of the switch.

### INDUSTRIAL APPLICABILITY

For example, the present disclosure can be utilized for driving an LED.

### LIST OF REFERENCE SYMBOLS

1 amplifier
2 error amplifier
3 oscillator
4 slope generation unit
5 PWM comparator
6 flip-flop
7 upper driver
8 lower driver
9 diode
10 comparator
11 HICCUP control unit
12 switch driving unit
13 comparator
14 recovery state monitoring unit
15 abnormality control unit
16 constant current circuit
17 comparator
18 pull-down resistor
19 communication unit
30 LED
35 microcomputer
100, 200, 300, 400 LED driving device
101, 102 LED driving device
Cboot boot capacitor
Cout output capacitor
Di clamp diode
HM upper transistor
L inductor
LM lower transistor
M1 transistor
R1 resistor
R11, R12 resistor
Rsns sense resistor
Msw switch
Tr1, Tr2 bipolar transistor
X1 to X4 light emitting device

1. A light emitting element driving device configured to drive a light emitting element, the light emitting element driving device comprising:
a switch driving unit configured to drive a switch connectable to a negative end of the light emitting element a positive end of which is grounded; and
an overcurrent detection unit configured to detect an overcurrent based on a voltage generated across both ends of a current detection resistor connected to a negative side of the switch,
wherein the switch driving unit is configured to switch the switch to an off-state when the overcurrent detection unit detects the overcurrent.

2. The light emitting element driving device according to claim 1, further comprising:
a recovery control unit configured to control the switch driving unit such that when the overcurrent detection unit detects the overcurrent, the switch driving unit switches the switch to an on-state after a predetermined standby time has elapsed.

3. The light emitting element driving device according to claim 1, further comprising:
a power short circuit detection unit configured to compare a voltage at the negative end of the light emitting element with a power short circuit detection threshold value,
wherein the switch driving unit is configured to keep the switch in the off-state while the power short circuit detection unit detects a power short circuit after the overcurrent detection unit has detected the overcurrent.

4. The light emitting element driving device according to claim 3,
wherein the negative end of the light emitting element is pulled down to a ground potential, and
the switch driving unit is configured to switch the switch to the on-state when the power short circuit detection unit detects that the voltage at the negative end has been lowered to the power short circuit detection threshold value.

5. The light emitting element driving device according to claim 1, further comprising:
a communication unit configured to communicate with a microcomputer,
wherein whether to recover from a protected state after the overcurrent has been detected according to information set by the microcomputer to the communication unit is switched.

6. The light emitting element driving device according to claim 1, further comprising:
an amplifier configured to amplify the voltage across the both ends of the current detection resistor,
wherein the overcurrent detection unit is a comparator connected to a front stage side of the amplifier.

7. A light emitting device comprising:
the light emitting element driving device according to claim 1;
a light emitting element that is driven by the light emitting element driving device;
a switch that is connected to a negative end of the light emitting element; and
a current detection resistor that is connected to a negative side of the switch.
